(19) United States
(12) Patent Application Publication
(10) Pub. No.: US 2025/0107215 A1
(43) Pub. Date: Mar. 27, 2025

(54) FRONT-END-OF-LINE (FEOL) CAPACITOR STRUCTURE

(71) Applicant: Taiwan Semiconductor Manufacturing Company, Ltd., Hsinchu (TW)

(72) Inventors: Jhu-Min Song, Nantou City (TW); Ying-Chou Chen, Taichung City (TW); Yi-Kai Ciou, Taoyuan City (TW); Chi-Te Lin, Hsinchu City (TW); Yi-Huan Chen, Hsin Chu City (TW); Chien-Chih Chou, Taipei City (TW); Fei-Yun Chen, Hinchu (TW); Yu-Chang Jong, Hsinchu City (TW)

(21) Appl. No.: 18/472,427

(22) Filed: Sep. 22, 2023

(51) Int. Cl. H01L 27/06; H01L 23/522

(52) U.S. Cl. CPC H10D 84/811; H01L 23/5223

(57) ABSTRACT

The present disclosure relates to an integrated chip. The integrated chip includes a first capacitor conductor disposed over an isolation structure arranged within a substrate. The isolation structure laterally extends past opposing outer sidewalls of the first capacitor conductor. A capacitor dielectric is arranged along one of the opposing outer sidewalls of the first capacitor conductor and over a top surface of the first capacitor conductor. A second capacitor conductor is arranged along an outer sidewall of the capacitor dielectric and over a top surface of the capacitor dielectric. The second capacitor conductor laterally overlaps parts of both the capacitor dielectric and the first capacitor conductor.

### BACKGROUND

Integrated chips are formed on semiconductor die comprising millions or billions of transistor devices. The transistor devices are configured to act as switches and/or to produce power gains so as to enable logical functionality for an integrated chip (e.g., form a processor configured to perform logic functions). Integrated chips also comprise passive devices, such as capacitors, resistors, inductors, varactors, etc. Passive devices are widely used to control integrated chip characteristics, such as gains, time constants, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip structure comprising a disclosed front-end-of-line (FEOL) capacitor.

FIG. 2 illustrates a cross-sectional view of some additional embodiments of an integrated chip structure comprising a disclosed FEOL capacitor.

FIGS. 3A-3C illustrate cross-sectional views of some embodiments of an integrated chip structure comprising a disclosed FEOL capacitor integrated with FEOL transistor devices.

FIG. 4 illustrates a cross-sectional view of some additional embodiments of an integrated chip structure comprising a disclosed FEOL capacitor integrated with FEOL transistor devices.

FIG. 5 illustrates a cross-sectional view of some additional embodiments of an integrated chip structure comprising a disclosed FEOL capacitor integrated with FEOL transistor devices.

FIGS. 6-27 illustrates cross-sectional views of some embodiments corresponding to a method of forming an integrated chip comprising a disclosed FEOL capacitor integrated with FEOL transistor devices.

FIG. 28 illustrates a flow diagram of some embodiments of a method of forming an integrated chip comprising a disclosed FEOL capacitor integrated with FEOL transistor devices.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Capacitors are devices that are used to store energy in an electric field generated by electrical charges that have accumulated on conductive plates of the capacitors. Capacitors typically comprise a first conductive plate separated from a second conductive plate by a dielectric. Modern day integrated chips comprise a wide variety of capacitors, which can be broadly categorized as front-end-of-line (FEOL) capacitors and back-end-of-line (BEOL) capacitors. FEOL capacitors are capacitors that are arranged on and/or within a substrate and may include MOS capacitors, PIP (polysilicon-insulator-polysilicon) capacitors, or the like. BEOL capacitors are capacitors that are arranged on and/or within a dielectric structure disposed over a substrate and may include MIM (metal-insulator-metal) capacitors, POP (metal-oxide-metal) capacitors, or the like.

FEOL capacitors are typically integrated onto a same substrate as other FEOL devices, such as low-voltage transistor devices, mid-voltage transistor devices, and high-voltage transistors devices. The integration of FEOL capacitors with other FEOL devices can lead to a number of problems with the FEOL capacitors. For example, FEOL PIP capacitors are typically formed over a p-doped substrate and have a high parasitic capacitance between a lower capacitor plate and the p-type substrate, while FEOL MOS capacitor have a capacitance that varies with a gate voltage so that a capacitance value is unstable when the gate voltage changes. Furthermore, the different structures of the capacitors and transistor devices complicates fabrication. For example, in emerging technology nodes (e.g., at 16 nm technology node and below), an extra hard-mask may be used during formation of a FEOL capacitor to protect a gate oxide of a high-voltage device and/or to avoid a logic fin recess process from consuming individual isolation structures within a substrate and thereby degrading electrical isolation between logic and high-voltage devices.

The present disclosure relates to an integrated chip comprising a FEOL capacitor (e.g., PIP capacitor) that is formed by a simple and low-cost fabrication process that utilizes process steps used to form other FEOL devices (e.g., high-voltage and logic transistor devices). In some embodiments, the disclosed FEOL capacitor includes a first capacitor conductor disposed over an isolation structure arranged within a substrate. The isolation structure laterally extends past opposing outermost sidewalls of the first capacitor conductor. A capacitor dielectric is arranged along one of the opposing outermost sidewalls of the first capacitor conductor and over a topmost surface of the first capacitor conductor. A second capacitor conductor is arranged along an outermost sidewall of the capacitor dielectric and over a topmost surface of the capacitor dielectric. The second capacitor conductor laterally overlaps parts of both the capacitor dielectric and the first capacitor conductor. By forming the second capacitor conductor to laterally overlap the capacitor dielectric and the first capacitor conductor, the second capacitor conductor is able to be formed from layers and processes used during fabrication of other FEOL devices thereby allow for the disclosed FEOL capacitor to be formed without adding costly fabrication processes. Furthermore, by forming the first capacitor conductor over the isolation structure, the disclosed FEOL capacitor is able to achieve stable operation.

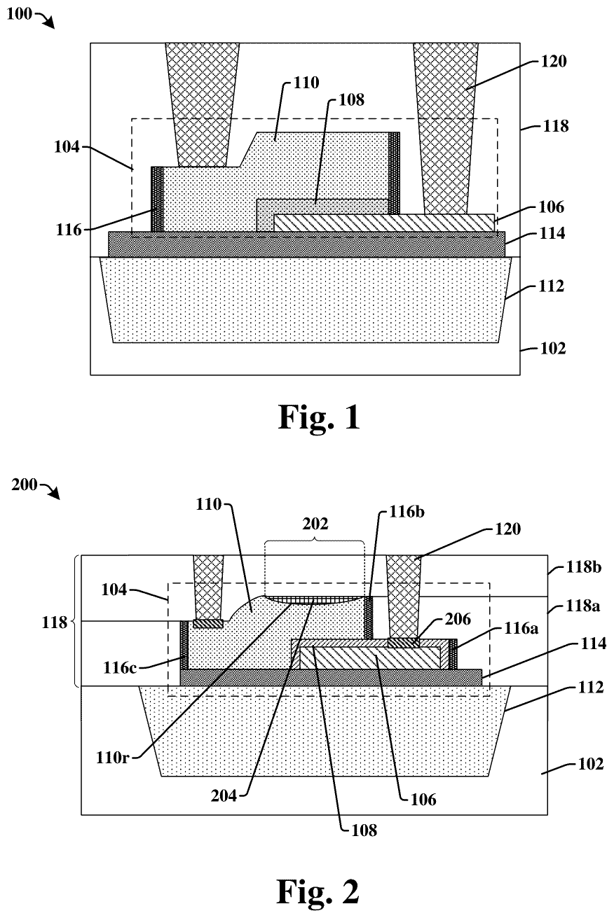

FIG. 1 illustrates a cross-sectional view of some embodiments of an integrated chip structure 100 comprising a disclosed front-end-of-line (FEOL) capacitor.

The integrated chip structure 100 comprises a FEOL capacitor 104 disposed over a substrate. 102. The FEOL capacitor 104 comprises a first capacitor conductor 106 separated from a second capacitor conductor 110 by a capacitor dielectric 108. The capacitor dielectric 108 extends along a sidewall and an upper surface of the first capacitor conductor 106. The second capacitor conductor 110 extends along a sidewall and an upper surface of the first capacitor conductor 106, so as to laterally extend from outside of the capacitor dielectric 108 and the first capacitor conductor 106 to directly over the capacitor dielectric 108 and the first capacitor conductor 106. The second capacitor conductor 110 also vertically extends from a bottom of the first capacitor conductor 106 to over a top of the first capacitor conductor 106, so that the capacitor dielectric 108 vertically and laterally separates the first capacitor conductor 106 from the second capacitor conductor 110.

In some embodiments, the second capacitor conductor 110 has a first upper surface outside of the capacitor dielectric 108 and a second upper surface over the capacitor dielectric 108 and the first capacitor conductor 106. In some embodiments, the second upper surface is vertically above the first upper surface, so that the second capacitor conductor 110 has a larger height directly over the first capacitor conductor 106 than laterally outside of the first capacitor conductor 106.

In some embodiments, a lower dielectric 114 is disposed over the substrate 102. The first capacitor conductor 106 and the second capacitor conductor 110 are disposed over the lower dielectric 114, such that the lower dielectric 114 extends along bottommost surfaces of the first capacitor conductor 106 and the second capacitor conductor 110. In some embodiments, the first capacitor conductor 106 contacts a first part of the lower dielectric 114, the capacitor dielectric 108 contacts a second part of the lower dielectric 114, and the second capacitor conductor 110 contacts a third part of the lower dielectric 114.

In some embodiments, the lower dielectric 114 is disposed onto an isolation structure 112 disposed on and/or within the substrate 102. In some embodiments, the isolation structure 112 comprises a shallow trench isolation (STI) structure disposed within a trench formed by one or more sidewalls of the substrate 102. In such embodiments, the isolation structure 112 comprises one or more dielectric materials disposed within the trench.

An inter-level dielectric (ILD) structure 118 is arranged over the substrate 102 and the FEOL capacitor 104. The ILD structure 118 laterally surrounds the FEOL capacitor 104 and the lower dielectric 114. In some embodiments, sidewall spacers 116 are arranged along an outermost sidewall of the capacitor dielectric 108 and along opposing outermost sidewalls of the second capacitor conductor 110. The sidewall spacers 116 laterally separate the capacitor dielectric 108 and the second capacitor conductor 110 from the ILD structure 118. Conductive interconnects 120 vertically extend through the ILD structure 118 to contact the first capacitor conductor 106 and the second capacitor conductor 110.

By having the second capacitor conductor 110 extends along a sidewall and an upper surface of the first capacitor conductor 106, the FEOL capacitor 104 can be formed by processing steps that are used to form other FEOL devices (e.g., logic transistor devices, high-voltage transistor devices, etc.). Therefore, the FEOL capacitor 104 can be formed without dedicated processing steps (e.g., masking and/or pattern steps) that could increase a cost of forming the integrated chip structure 100. Furthermore, by separating the FEOL capacitor 104 from the substrate 102 by an isolation structure 112 and a lower dielectric 114, the FEOL capacitor 104 can be formed to have a stable capacitance and a small parasitic capacitance.

FIG. 2 illustrates a cross-sectional view of some additional embodiments of an integrated chip structure 200 comprising a disclosed FEOL capacitor.

The integrated chip structure 200 comprises a FEOL capacitor 104 disposed over a substrate 102. The FEOL capacitor 104 comprises a first capacitor conductor 106 separated from a second capacitor conductor 110 by a capacitor dielectric 108. The capacitor dielectric 108 extends along opposing outermost sidewalls and an upper surface of the first capacitor conductor 106. The second capacitor conductor 110 laterally extends from outside of the capacitor dielectric 108 and the first capacitor conductor 106 to directly over the capacitor dielectric 108 and the first capacitor conductor 106.

The first capacitor conductor 106 comprises a first conductive material and the second capacitor conductor 110 comprises a second conductive material. In some embodiments, the first conductive material and the second conductive material may comprise or be doped polysilicon, titanium, titanium nitride, tantalum, tantalum nitride, and/or the like. In some embodiments, the first conductive material may be a same material (e.g., doped polysilicon) as the second conductive material. In other embodiments, the first conductive material may comprise or be a first material (e.g., titanium nitride) and the second conductive material may comprise or be a different second material (e.g., doped polysilicon). The capacitor dielectric 108 may comprise an oxide (e.g., silicon dioxide), a nitride (e.g., silicon nitride, silicon oxynitride, etc.), a carbide (e.g., silicon carbide, silicon oxycarbide, etc.), and/or the like.

In some embodiments, the second capacitor conductor 110 has a curved upper surface 110r forming a recess 202 that is depressed below a highest point of the second capacitor conductor 110. In some embodiments, the recess 202 laterally extends from directly over the first capacitor conductor 106 to laterally outside of the first capacitor conductor 106. In some embodiments, the highest point of the second capacitor conductor 110 is laterally outside of the first capacitor conductor 106. The recess 202 causes the second capacitor conductor 110 to have a larger width along an outermost sidewall of the second capacitor conductor 110 than between the outermost sidewall and a lateral center of the second capacitor conductor 110.

In some embodiments, a metallic inset 204 is disposed within the recess 202 in the second capacitor conductor 110. The metallic inset 204 may have a curved lower surface facing the second capacitor conductor 110 and a substantially flat upper surface facing away from the second capacitor conductor 110. In some embodiments, the metallic inset 204 may comprise or be tungsten, ruthenium, and/or the like.

The FEOL capacitor 104 is vertically separated from the substrate 102 by way of an isolation structure 112 and a lower dielectric 114. The isolation structure 112 is disposed within a trench formed by sidewalls of the substrate 102. The lower dielectric 114 is arranged on the isolation structure 112. In some embodiments, the isolation structure 112 may laterally extend past opposing outermost sidewalls of the lower dielectric 114. The FEOL capacitor 104 is laterally set-back from the opposing outermost sidewalls of the lower dielectric 114. In some embodiments, the FEOL capacitor 104 may be laterally set-back from the opposing outermost sidewalls of the lower dielectric 114 by different distances. For example, an outermost sidewall of the second capacitor conductor 110 may be laterally set from a first outermost sidewall of the lower dielectric 114 by a first distance and an outermost sidewall of the first capacitor conductor 106 may be laterally set back from a second outermost sidewall of the lower dielectric 114 by a second distance that is different than the first distance.

In some embodiments, sidewall spacers 116a-116c may be arranged along an outermost sidewall of the capacitor dielectric 108 and along opposing outermost sidewalls of the second capacitor conductor 110. In some embodiments, the sidewall spacers 116a-116c may comprise a first sidewall spacer 116a, a second sidewall spacer 116b, and a third sidewall spacer 116c. The first sidewall spacer 116a is arranged along an outermost sidewall of the capacitor dielectric 108. The capacitor dielectric 108 laterally separates the first sidewall spacer 116a from the first capacitor conductor 106. The second sidewall spacer 116b is arranged on an upper surface of the capacitor dielectric 108 and along a first outermost sidewall of the second capacitor conductor 110. The third sidewall spacer 116c is arranged along a second outermost sidewall of the second capacitor conductor 110.

In some embodiments, the third sidewall spacer 116c may be substantially aligned with the first outermost sidewall of lower dielectric 114 and the first sidewall spacer 116a may be set-back from the second outermost sidewall of the lower dielectric 114. In such embodiments, the lower dielectric 114 laterally extends from an outermost sidewall of the third sidewall spacer 116c to laterally past an outermost sidewall of the first sidewall spacer 116a. In some embodiments, the first sidewall spacer 116a, the second sidewall spacer 116b, and the third sidewall spacer 116c have topmost surfaces that are at different heights over the substrate 102.

An inter-level dielectric (ILD) structure 118 is arranged over the substrate 102. In some embodiments, the ILD structure 118 continuously extends from over the metallic inset 204 to along sidewalls of the second capacitor conductor 110 and the lower dielectric 114. In some embodiments, the ILD structure 118 may comprise a first ILD layer 118a surrounding opposing sides of the second capacitor conductor 110 and a second ILD layer 118b over the first ILD layer 118a and the second capacitor conductor 110. In some embodiments, the first ILD layer 118a may have an uppermost surface that is at or below an uppermost surface of the second capacitor conductor 110. In some embodiments, the first ILD layer 118a and the second ILD layer 118b may comprise or be one or more of silicon dioxide, carbon doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like.

Conductive interconnects 120 vertically extend through the ILD structure 118 to electrically contact the first capacitor conductor 106 and the second capacitor conductor 110. In some embodiments, the conductive interconnects 120 may comprise conductive contacts that vertically extend through the ILD structure 118 to contact the first capacitor conductor 106 and the second capacitor conductor 110. In some embodiments, the conductive interconnects 120 may be electrically coupled to the first capacitor conductor 106 and the second capacitor conductor 110 by way of a silicide 206.

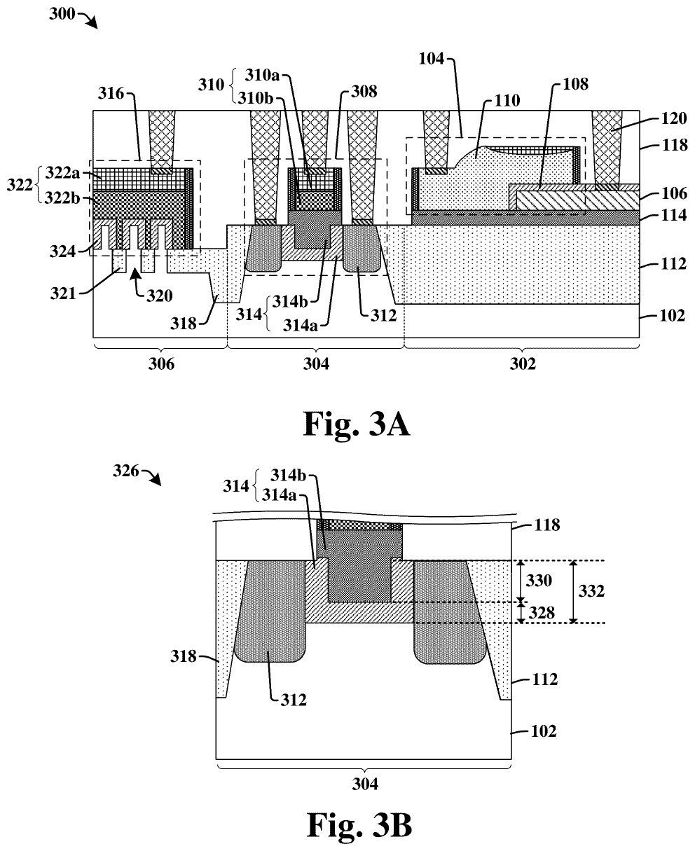

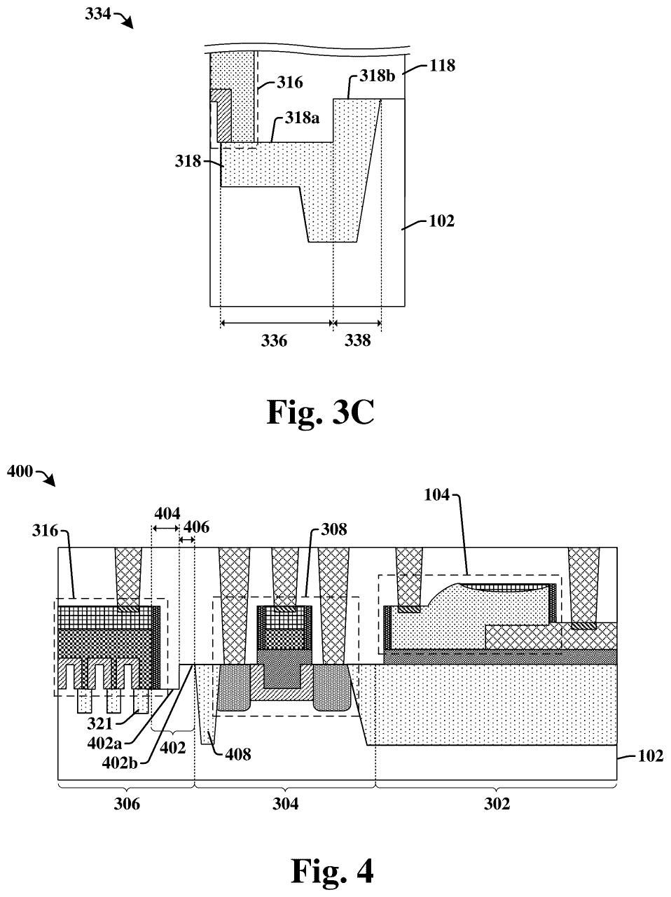

FIG. 3A illustrates a cross-sectional view of some embodiments of an integrated chip structure 300 comprising a disclosed FEOL capacitor integrated with FEOL transistor devices.

The integrated chip structure 300 comprises a substrate 102 having a capacitor region 302, a high-voltage region 304, and a logic region 306. A disclosed FEOL capacitor 104 is disposed over the substrate 102 and within the capacitor region 302. The disclosed FEOL capacitor 104 comprises a first capacitor conductor 106 separated from a second capacitor conductor 110 by a capacitor dielectric 108. In some embodiments, the second capacitor conductor 110 is arranged at least partially above and laterally outside of the first capacitor conductor 106.

A high-voltage transistor device 308 is disposed within the high-voltage region 304. The high-voltage transistor device 308 comprises a high-voltage gate structure 310 disposed over a high-voltage gate dielectric 314. Source/drain regions 312 are disposed within the substrate 102 on opposing sides of the high-voltage gate structure 310. In some embodiments, the high-voltage gate dielectric 314 may be arranged within a high-voltage gate dielectric recess within the substrate 102. The high-voltage gate dielectric recess is formed by sidewalls and a recessed surface of the substrate 102. The high-voltage gate dielectric recess allows for the high-voltage gate dielectric 314 to be formed to a relatively large thickness without causing planarization issues during fabrication of the integrated chip structure 300.

In some embodiments, the high-voltage gate dielectric 314 may comprise a first high-voltage gate dielectric 314a and a second high-voltage gate dielectric 314b. The first high-voltage gate dielectric 314a is arranged along the sidewalls and the recessed surface of the substrate 102 that form the high-voltage gate dielectric recess. The second high-voltage gate dielectric 314b is arranged over the first high-voltage gate dielectric 314a. In some embodiments, outermost sidewalls of the second high-voltage gate dielectric 314b may be laterally set-back from outermost sidewalls of the first high-voltage gate dielectric 314a.

In some embodiments, the high-voltage gate structure 310 may comprise a high-voltage metal gate 310b and a high-voltage metal cap 310a disposed over the high-voltage metal gate 310b. In some embodiments, the high-voltage metal gate 310b may comprise or be an n-type metal (e.g., aluminum, tantalum, titanium, hafnium, or the like) or a p-type metal (e.g., nickel, cobalt, molybdenum, platinum, lead, gold, or the like). In various embodiments, the high-voltage metal cap 310a may comprise or be tungsten, ruthenium, titanium, and/or the like.

A logic transistor device 316 is disposed within the logic region 306. The logic transistor device 316 has a first threshold voltage (e.g., 1.8 volts (V)) that is smaller than a second voltage of the high-voltage transistor device 308. The logic transistor device 316 comprises a logic gate structure 322 disposed over a logic gate dielectric 324. The logic gate dielectric 324 may be arranged along sidewalls and an upper surface of one or more fins of semiconductor material 320 that protrude outward from an upper surface of the substrate 102. In some embodiments, the one or more fins of semiconductor material 320 are laterally separated from one another by way of one or more fin isolation structures 321. Source/drain regions (not shown) are disposed within the substrate 102 on opposing sides of the logic gate structure 322. In some embodiments, a channel region of the logic transistor device 316 may be disposed within the one or more fins of semiconductor material 320 and may extend between the source/drain regions along a line extending into the paper.

In some embodiments, the logic gate structure 322 may comprise a logic metal gate 322b and a logic metal cap 322a disposed over the logic metal gate 322b. In some embodiments, the logic metal gate 322b may comprise or be an n-type metal (e.g., aluminum, tantalum, titanium, hafnium, or the like) or a p-type metal (e.g., nickel, cobalt, molybdenum, platinum, lead, gold, or the like). In various embodiments, the logic metal cap 322a may comprise or be tungsten, ruthenium, titanium, and/or the like.

In some embodiments, a boundary isolation structure 318 may be disposed between the high-voltage region 304 and the logic region 306. An ILD structure 118 is arranged over the substrate 102. Conductive interconnects 120 vertically extend through the ILD structure 118 to contact the first capacitor conductor 106, the second capacitor conductor 110, the source/drain regions 312, the high-voltage gate structure 310, and the logic gate structure 322.

FIG. 3B illustrates a cross-sectional view 326 showing some embodiments of a high-voltage gate dielectric 314 arranged within the high-voltage region 304 of the substrate 102.

As shown in cross-sectional view 326, the high-voltage gate dielectric 314 comprises a first high-voltage gate dielectric 314a and a second high-voltage gate dielectric 314b over the first high-voltage gate dielectric 314a. The first high-voltage gate dielectric 314a has a first thickness 328 and the second high-voltage gate dielectric 314b has a second thickness 330 extending from a bottom of the second high-voltage gate dielectric 314b to an upper surface of the substrate 102. The first high-voltage gate dielectric 314a and the second high-voltage gate dielectric 314b provide for a collective thickness 332 measured between a bottom of the first high-voltage gate dielectric 314a and the upper surface of the substrate 102.

In some embodiments, the high-voltage transistor device (308 of FIG. 3A) may have a threshold voltage that is in a range of between approximately 4 V and approximately 8V. In such embodiments, the first thickness 328 may be in a range of between approximately 100 Angstroms (Å) and approximately 150 Å, between approximately 110 Å and approximately 130 Å, or other similar values; the second thickness 330 may be in a range of between approximately 90 Å and approximately 130 Å, between approximately 100 Å and approximately 120 Å, or other similar values; and the collective thickness 332 may be in a range of between approximately 200 Å and approximately 300 Å, between approximately 210 Å and approximately 250 Å, or other similar values.

In other embodiments, the high-voltage transistor device (308 of FIG. 3A) may have a threshold voltage that is in a range of between approximately 20 V and approximately 35 V. In such embodiments, the first thickness 328 may be in a range of between approximately 100 Å and approximately 150 Å, between approximately 120 Å and approximately 140 Å, or other similar values; the second thickness 330 may be in a range of between approximately 700 Å and approximately 1300 Å, between approximately 800 Å and approximately 1200 Å, or other similar values; and the collective thickness 332 may be in a range of between approximately 800 Å and approximately 1500 Å, between approximately 920 Å and approximately 1360 Å, or other similar values. In yet other embodiments, the high-voltage transistor device (308 of FIG. 3A) may have a threshold voltage that is larger than 35 V. In such embodiments, the first thickness 328, the second thickness 330, and the collective thickness 332 may be larger than the above ranges.

FIG. 3C illustrates a cross-sectional view 334 showing some embodiments of a boundary isolation structure 318 disposed between the high-voltage region (304 of FIG. 3A) and the logic region (306 of FIG. 3A).

As shown in cross-sectional view 334, the boundary isolation structure 318 comprises a first upper surface 318a and a second upper surface 318b over the first upper surface 318a. The first upper surface 318a is laterally between the second upper surface 318b and the logic transistor device 316. In some embodiments, the first upper surface 318a may have a first length 336 and the second upper surface 318b may have a second length 338. In some embodiments, the first length 336 is larger than the second length 338.

In some embodiments, the high-voltage transistor device (308 of FIG. 3A) may have a threshold voltage that is in a range of between approximately 4 V and approximately 8 V. In such embodiments, the first length 336 may be in a range of between approximately 0.1 microns (μm) and approximately 0.5 μm, between approximately 0.2 μm and approximately 0.3 μm, or other similar values; and the second length 338 may be in a range of between approximately 0.05 μm and approximately 0.4 μm, between approximately 0.1 μm and approximately 0.2 μm, or other similar values.

In other embodiments, the high-voltage transistor device (308 of FIG. 3A) may have a threshold voltage that is in a range of between approximately 20 V and approximately 35 V. In such embodiments, the first length 336 may be in a range of between approximately 0.1 μm and approximately 0.5 μm, between approximately 0.25 μm and approximately 0.35 μm, or other similar values; and the second length 338 may be in a range of between approximately 0.05 μm and approximately 0.4 μm, between approximately 0.15 μm and approximately 0.25 μm, or other similar values. In yet other embodiments, the high-voltage transistor device (308 of FIG. 3A) may have a threshold voltage that is larger than 35 V. In such embodiments, the first length 336 and the second length 338 may be larger than the above ranges.

FIG. 4 illustrates a cross-sectional view of some additional embodiments of an integrated chip structure 400 comprising a disclosed FEOL capacitor integrated with FEOL transistor devices.

The integrated chip structure 400 comprises a substrate 102 having a capacitor region 302, a high-voltage region 304, and a logic region 306. A FEOL capacitor 104 is disposed within the capacitor region 302, a high-voltage transistor device 308 is disposed within the high-voltage region 304, and a logic transistor device 316 is disposed within the logic region 306.

The substrate 102 has a stepped region 402 that is laterally between a high-voltage isolation structure 408 within the high-voltage region 304 and a closest of one or more fin isolation structures 321 within the logic region 306. The stepped region 402 comprises a first upper surface 402a and a second upper surface 402b over the first upper surface 402a. The first upper surface 402a is laterally between the second upper surface 402b and the logic transistor device 316. In some embodiments, the first upper surface 402a may have a first length 404 and the second upper surface 402b may have a second length 406. In some embodiments, the first length 404 is larger than the second length 406.

In some embodiments, the high-voltage transistor device 308 may have a threshold voltage that is in a range of between approximately 4 V and approximately 8 V. In such embodiments, the first length 404 may be in a range of between approximately 0.3 μm and approximately 0.6 μm, between approximately 0.4 μm and approximately 0.5 μm, or other similar values; and the second length 406 may be in a range of between approximately 0.2 μm and approximately 0.5 μm, between approximately 0.3 μm and approximately 0.4 μm, or other similar values.

In other embodiments, the high-voltage transistor device 308 may have a threshold voltage that is in a range of between approximately 20 V and approximately 35 V. In such embodiments, the first length 404 may be in a range of between approximately 0.4 μm and approximately 0.6 μm, between approximately 0.45 μm and approximately 0.55 μm, or other similar values; and the second length 406 may be in a range of between approximately 0.3 μm and approximately 0.5 μm, between approximately 0.35 μm and approximately 0.45 μm, or other similar values. In yet other embodiments, the high-voltage transistor device 308 may have a threshold voltage that is larger than 35 V. In such embodiments, the first length 404 and the second length 406 may be larger than the above ranges.

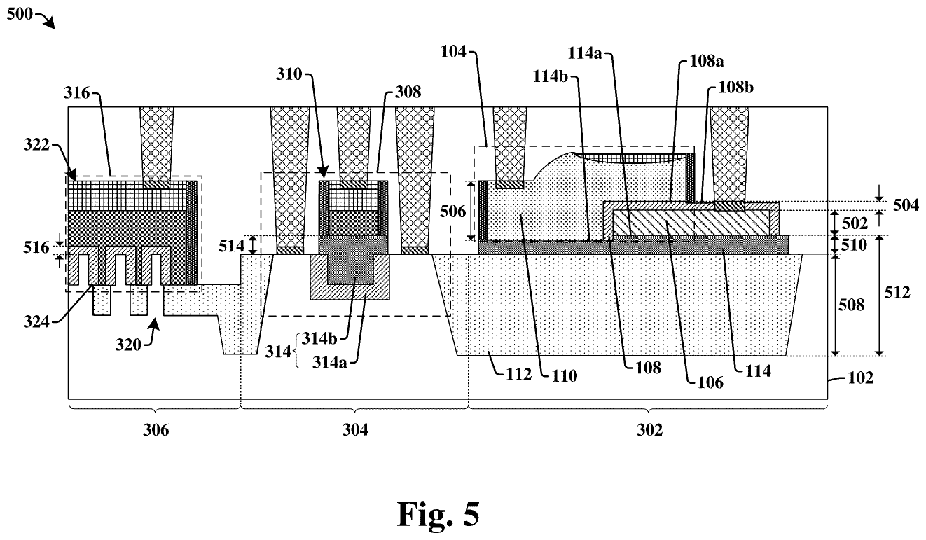

FIG. 5 illustrates a cross-sectional view of some additional embodiments of an integrated chip structure 500 comprising a disclosed FEOL capacitor integrated with FEOL transistor devices.

The integrated chip structure 500 comprises a substrate 102 having a capacitor region 302, a high-voltage region 304, and a logic region 306. A FEOL capacitor 104 is disposed within the capacitor region 302, a high-voltage transistor device 308 is disposed within the high-voltage region 304, and a logic transistor device 316 is disposed within the logic region 306.

The FEOL capacitor 104 comprises a first capacitor conductor 106 separated from a second capacitor conductor 110 by a capacitor dielectric 108. A lower dielectric 114 is arranged below the FEOL capacitor 104 and an isolation structure 112 is arranged below the lower dielectric 114. In some embodiments, the lower dielectric 114 may have a first upper surface 114a directly below the first capacitor conductor 106 and a second upper surface 114b laterally outside of the first capacitor conductor 106. In some embodiments, the first upper surface 114a may be above the second upper surface 114b.

The first capacitor conductor 106 has a thickness 502 that is in a range of between approximately 150 Å and approximately 300 Å, between approximately 175 Å and approximately 250 Å, approximately 200 Å, or other similar values. The capacitor dielectric 108 has a thickness 504 that is in a range of between approximately 25 Å and approximately 75 Å, between approximately 40 Å and approximately 50 Å, approximately 45 Å, or other similar values. The second capacitor conductor 110 has a thickness 506 that is in a range of between approximately 500 Å and approximately 1500 Å, between approximately 750 Å and approximately 1250 Å, approximately 1000 Å, or other similar values.

The isolation structure 112 has a thickness 508 that is in a range of between approximately 2000 Å and approximately 5000 Å, between approximately 2500 Å and approximately 4000 Å, approximately 3000 Å, or other similar values. The lower dielectric 114 has a thickness 510 that is in a range of between approximately 100 Å and approximately 200 Å, between approximately 125 Å and approximately 175 Å, approximately 140 Å, or other similar values. The first capacitor conductor 106 is vertically separated from the substrate 102 by a distance 512 that is in a range of between approximately 3000 Å and approximately 3500 Å, between approximately 3100 Å and approximately 3250 Å, or other similar values.

The high-voltage transistor device 308 comprises a high-voltage gate structure 310 separated from the substrate 102 by a high-voltage gate dielectric 314 comprising a first high-voltage gate dielectric 314a and a second high-voltage gate dielectric 314b. In some embodiments, the second high-voltage gate dielectric 314b and the lower dielectric 114 are a same material (e.g., high temperature silicon dioxide). In some embodiments, a thickness 514 of the outermost sidewalls of the second high-voltage gate dielectric 314b and the thickness 510 of the lower dielectric 114 are substantially equal. In some embodiments, the second high-voltage gate dielectric 314b has an upper surface that is substantially co-planar with an upper surface of the lower dielectric 114.

The logic transistor device 316 comprises a logic gate structure 322 separated from the substrate 102 by a logic gate dielectric 324 extending along sidewalls and an upper surface of one or more fins of semiconductor material 320. In some embodiments, the logic gate dielectric 324 and the capacitor dielectric 108 are a same material (e.g., an oxide). In some embodiments, the logic gate dielectric 324 may have a thickness 516 that is substantially equal to the thickness 504 of the capacitor dielectric 108.

It will be appreciated that the disclosed integrated chip structures (e.g., integrated chip structures 300, 400, and/or 500) may be implemented in a wide range of applications. For example, the disclosed integrated chip structures may be implemented within a bipolar-CMOS-DMOS (BCD), a driver integrated chip (IC), an image sensor, a power management device, an image signal process (ISP), or the like.

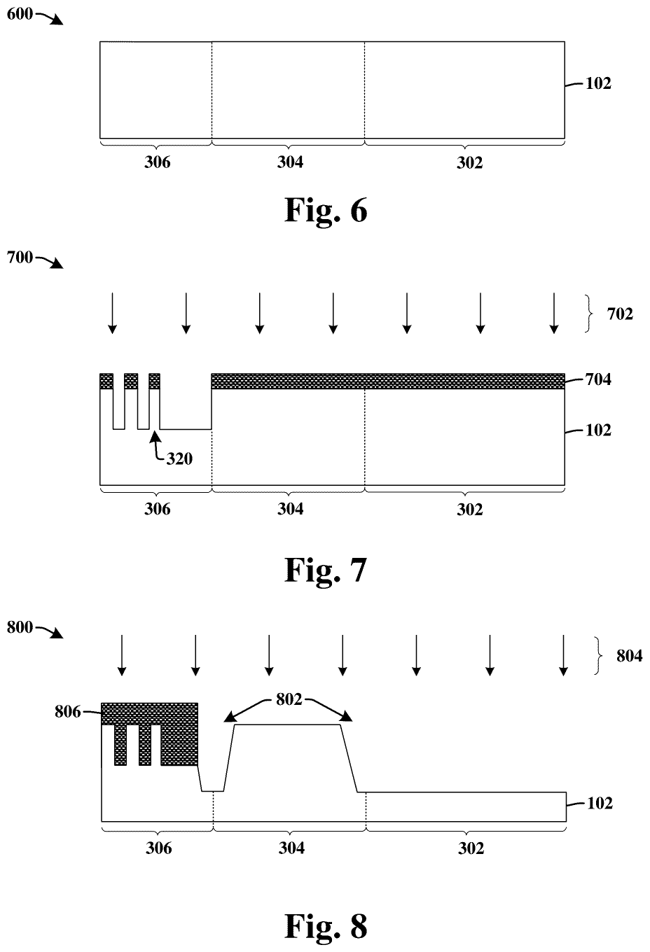

FIGS. 6-27 illustrates cross-sectional views 600-2700 of some embodiments corresponding to a method of forming an integrated chip comprising a disclosed FEOL capacitor integrated with FEOL transistor devices. Although FIGS. 6-27 are described in relation to a method, it will be appreciated that the structures disclosed in the method are not limited to the method, but instead may stand alone as structures independent of the method.

As shown in cross-sectional view 600 of FIG. 6, a substrate 102 is provided. In various embodiments, the substrate 102 may be any type of semiconductor body (e.g., silicon, SiGe, etc.), such as a semiconductor wafer and/or one or more die on a wafer, as well as any other type of semiconductor and/or epitaxial layers, associated therewith. In some embodiments, the substrate 102 may comprise a p-type doping. The substrate 102 comprises a capacitor region 302, a high-voltage region 304, and a logic region 306. In some embodiments, the high-voltage region 304 may neighbor the logic region 306.

As shown in cross-sectional view 700 of FIG. 7, the substrate 102 is patterned to form one or more fins of semiconductor material 320 within the logic region 306. The one or more fins of semiconductor material 320 are formed by etching the substrate 102 to form sidewall of the substrate 102 that protrude outward from a recessed surface of the substrate 102. In some embodiments, the substrate 102 may be patterned by selectively exposing the substrate 102 to an etchant 702 according to a mask 704. In some embodiments, the etchant 702 may comprise a dry etchant (e.g., comprising fluorine, chlorine, and/or the like). In some embodiments, the mask 704 may comprise a photosensitive material (e.g., a photoresist), a hard mask, and/or the like.

As shown in cross-sectional view 800 of FIG. 8, one or more trenches 802 are formed within the substrate 102. In some embodiments, the one or more trenches 802 may be formed by selectively etching the substrate 102. In some embodiments, the substrate 102 may be selectively etched by forming a mask 806 over the substrate 102, and subsequently exposing the substrate 102 to an etchant 804 configured to selectively remove unmasked parts of the substrate 102 and form the one or more trenches 802. In various embodiments, the etchant 804 may comprise a dry etchant having an etching chemistry comprising a fluorine species (e.g., CF₄, CHF₃, C₄F₈, etc.) or a wet etchant comprising hydrofluoric acid (HF), potassium hydroxide (KOH), or the like. In some embodiments, the mask 806 may be formed over a pad oxide layer (not shown) arranged along an upper surface of the substrate 102. In some embodiments, the one or more trenches 802 may be arranged within the substrate 102 within the capacitor region 302 and along a border between the high-voltage region 304 and the logic region 306.

As shown in cross-sectional view 900 of FIG. 9, an isolation structure 112 and a boundary isolation structure 318 are formed within the one or more trenches 802 within the substrate 102. In some embodiments, the isolation structure 112 and the boundary isolation structure 318 may be formed by forming one or more dielectric materials within the one or more trenches 802. In some embodiments, the one or more dielectric materials may also be formed between adjacent ones of the one or more fins of semiconductor material to form one or more fin isolation structures 321.

In some embodiments, the one or more dielectric materials may comprise an oxide (e.g., silicon oxide), a nitride, a carbide, or the like. In some embodiments, the one or more dielectric materials may be formed by way of a deposition process (e.g., physical vapor deposition (PVD), chemical vapor deposition (CVD), PE-CVD, atomic layer deposition (ALD), sputtering, etc.). In some embodiments, the one or more dielectric materials may be formed by performing a thermal oxidation process with a mask (e.g., mask 806 of FIG. 8) in place over the substrate 102, followed by a deposition process to fill the one or more trenches 802 with the one or more dielectric materials. After filling the one or more trenches 802 with the one or more dielectric materials, a planarization process (e.g., a chemical mechanical planarization process) may be performed to remove the mask and excess of the one or more dielectric materials over the substrate 102.

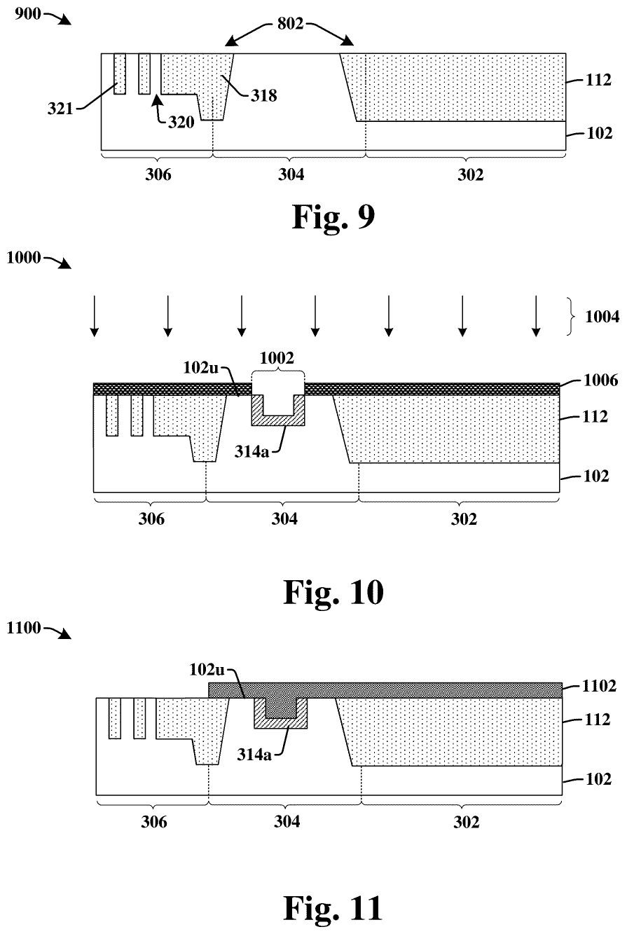

As shown in cross-sectional view 1000 of FIG. 10, the substrate 102 is selectively patterned to form a high-voltage gate dielectric recess 1002 within an upper surface 102u of the substrate 102 and within the high-voltage region 304. The substrate 102 may be selectively patterned by exposing the substrate 102 to an etchant 1004 according to a mask 1006 to form the sidewalls of the substrate 102 that form the high-voltage gate dielectric recess 1002. After formation of the high-voltage gate dielectric recess 1002, a first high-voltage dielectric 314a is formed along the sidewalls and an upper surface of the substrate 102 that form the high-voltage gate dielectric recess 1002. In some embodiments, the first high-voltage dielectric 314a may be formed by way of a thermal oxidation process (e.g., a dry thermal oxidation process or a wet thermal oxidation process). In some embodiments, the first high-voltage dielectric 314a may be formed to a thickness that is in a range of between approximately 5 Å and approximately 50 Å, between approximately 10 Å and approximately 50 Å, or other similar values.

As shown in cross-sectional view 1100 of FIG. 11, a second high-voltage dielectric layer 1102 is formed over the upper surface 102u of the substrate 102 and over the first high-voltage dielectric 314a. In some embodiments, the second high-voltage dielectric layer 1102 is formed to continuously extend from directly over the first high-voltage dielectric 314a to over the isolation structure 112 within the capacitor region 302. In some embodiments, the second high-voltage dielectric layer 1102 may comprise a high temperature oxide (e.g., high temperature silicon dioxide). In some such embodiments, the second high-voltage dielectric layer 1102 may be formed by the reaction of nitrogen gas (N₂O) and dichlorosilane during a low pressure chemical vapor deposition (LP-CVD) process.

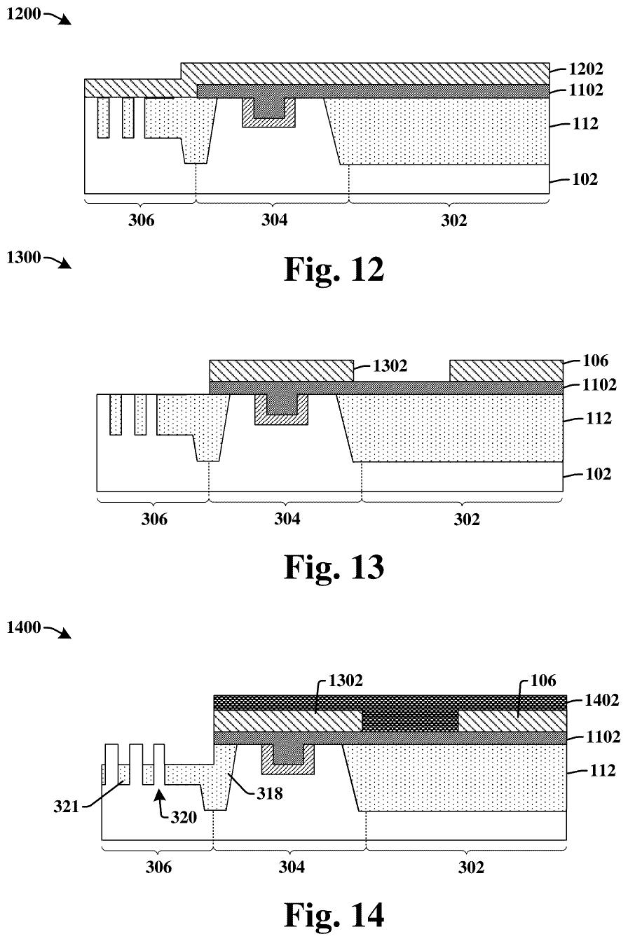

As shown in cross-sectional view 1200 of FIG. 12, a first conductive layer 1202 is formed over the second high-voltage dielectric layer 1102. In some embodiments, the first conductive layer 1202 may be formed along an upper surface and a sidewall of the second high-voltage dielectric layer 1102. In such embodiments, the first conductive layer 1202 may be formed to continuously extend from within the capacitor region 302, to within the high-voltage region 304, and to within the logic region 306.

In various embodiments, the first conductive layer 1202 may comprise or be doped polysilicon, titanium nitride, or the like. In some embodiments, the first conductive layer 1202 may be formed to a thickness that is in a range of between approximately 150 Å and approximately 300 Å, between approximately 175 Å and approximately 250 Å, approximately 200 Å, or other similar values. In some embodiments, the first conductive layer 1202 may be formed by way of a deposition process (e.g., PVD, CVD, PE-CVD, or the like).

As shown in cross-sectional view 1300 of FIG. 13, the first conductive layer (1202 of FIG. 12) is selectively patterned to form a first capacitor conductor 106, to form a high-voltage mask 1302, and to remove the first conductive layer from within the logic region 306. The first capacitor conductor 106 is formed over the isolation structure 112, such that the isolation structure 112 laterally extends from directly below the first capacitor conductor 106 to past an outermost sidewall of the first capacitor conductor 106. The high-voltage mask 1302 is formed to protect the high-voltage gate dielectric 314 from damage during subsequent etching processes.

As shown in cross-sectional view 1400 of FIG. 14, the boundary isolation structure 318 and the one or more fin isolation structures 321 are selectively etched within the logic region 306. Selectively etching the boundary isolation structure 318 and the one or more fin isolation structures 321 recesses the boundary isolation structure 318 and the one or more fin isolation structures 321 to the expose upper portions of the sidewalls of the substrate 102 that form the one or more fins of semiconductor material 320. In some embodiments, the boundary isolation structure 318 and the one or more fin isolation structures 321 may be etched with a mask 1402 in place to cover the capacitor region 302 and the high-voltage region 304.

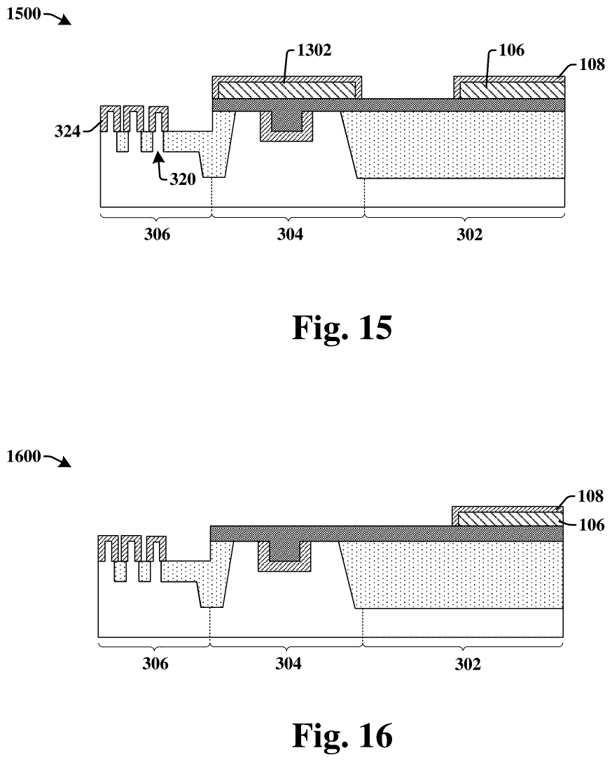

As shown in cross-sectional view 1500 of FIG. 15, a logic gate dielectric 324 is formed onto exposed surfaces of the one or more fins of semiconductor material 320. For example, the logic gate dielectric 324 may be formed onto the upper portions of the sidewalls of the substrate 102 and onto upper surfaces of the substrate 102 that form the one or more fins of semiconductor material 320. In some embodiments, the logic gate dielectric 324 may also be formed onto opposing sidewalls and an uppermost surface of the high-voltage mask 1302. In some embodiments, a capacitor dielectric 108 may be concurrently formed onto opposing sidewalls and an uppermost surface of the first capacitor conductor 106.

In some embodiments, the logic gate dielectric 324 and the capacitor dielectric 108 may be formed to a thickness that is in a range of between approximately 25 Å and approximately 75 Å, between approximately 40 Å and approximately 50 Å, approximately 45 Å, or other similar values. In some embodiments, the logic gate dielectric 324 and the capacitor dielectric 108 may be formed by way of a same thermal oxidation process. In other embodiments, the logic gate dielectric 324 and the capacitor dielectric 108 may be formed by way of a same deposition process (e.g., PVD, CVD, PE-CVD, or the like).

As shown in cross-sectional view 1600 of FIG. 16, the high-voltage mask 1302 is removed from within the high-voltage region 304. In some embodiments, the high-voltage mask 1302 may be removed by way of an etching process.

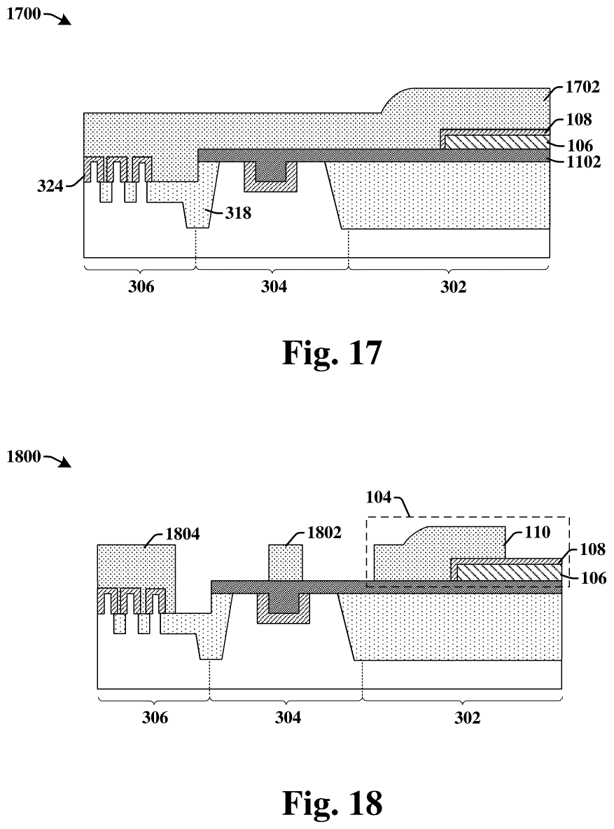

As shown in cross-sectional view 1700 of FIG. 17, a second conductive layer 1702 is formed over the substrate 102. In some embodiments, the second conductive layer 1702 may be formed along upper surfaces and sidewalls of the second high-voltage dielectric layer 1102, the capacitor dielectric 108, the logic gate dielectric 324, and the boundary isolation structure 318. In such embodiments, the second conductive layer 1702 may be formed to continuously extend from within the capacitor region 302, to within the high-voltage region 304, and to within the logic region 306.

In some embodiments, the second conductive layer 1702 may comprise or be doped polysilicon, titanium nitride, and/or the like. In some embodiments, the second conductive layer 1702 may be formed to a thickness that is in a range of between approximately 500 Å and approximately 1500 Å, between approximately 750 Å and approximately 1250 Å, approximately 1000 Å, or other similar values. In some embodiments, the second conductive layer 1702 may be formed by way of a deposition process (e.g., PVD, CVD, PE-CVD, or the like).

As shown in cross-sectional view 1800 of FIG. 18, the second conductive layer (1702 of FIG. 17) is selectively patterned to form a second capacitor conductor 110, a high-voltage sacrificial gate structure 1802, and a logic sacrificial gate structure 1804. The second capacitor conductor 110 is formed to laterally extend from directly above the first capacitor conductor 106 to past an outermost sidewall of the first capacitor conductor 106. Collectively the first capacitor conductor 106, the capacitor dielectric 108, and the second capacitor conductor 110 form a FEOL capacitor 104. In some embodiments, the second conductive layer may be selectively patterned by forming a mask over the second conductive layer, and subsequently exposing the second conductive layer to an etchant configured to selectively remove unmasked parts of the second conductive layer. In various embodiments, the etchant may comprise a dry etchant having an etching chemistry comprising a fluorine species (e.g., CF₄, CHF₃, C₄F₈, etc.) or a wet etchant comprising hydrofluoric acid (HF), potassium hydroxide (KOH), or the like.

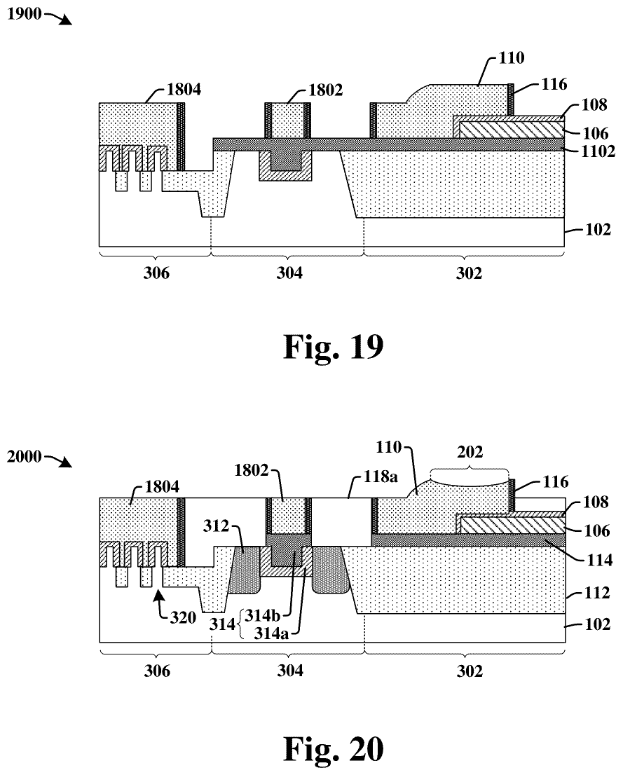

As shown in cross-sectional view 1900 of FIG. 19, sidewall spacers 116 are formed on opposing sides of the second capacitor conductor 110, the high-voltage sacrificial gate structure 1802, and the logic sacrificial gate structure 1804. The sidewall spacers 116 may be formed by depositing a spacer layer over the substrate 102. In some embodiments, the spacer layer may be deposited by a deposition technique (e.g., PVD, CVD, PE-CVD, ALD, sputtering, etc.) to a thickness in a range of between approximately 400 angstroms and approximately 600 angstroms. The spacer layer is subsequently etched to remove the spacer layer from horizontal surfaces, leaving the sidewall spacers 116 along opposing sides of the second capacitor conductor 110, the high-voltage sacrificial gate structure 1802, and the logic sacrificial gate structure 1804. In various embodiments, the spacer layer may comprise silicon nitride, silicon dioxide (SiO₂), silicon oxy-nitride (e.g., SiON), or the like.

As shown in cross-sectional view 2000 of FIG. 20, the second high-voltage dielectric layer (1102 of FIG. 19) is selectively patterned to form a lower dielectric 114 on the isolation structure 112 and to further form a second high-voltage gate dielectric 314b over the first high-voltage gate dielectric 314a. Collectively the first high-voltage gate dielectric 314a and the second high-voltage gate dielectric 314b form a high-voltage gate dielectric 314 that separates the high-voltage sacrificial gate structure 1802 from the substrate 102.

After patterning the second high-voltage dielectric layer, source/drain regions 312 may be formed within the high-voltage region 304 on opposing sides of the high-voltage sacrificial gate structure 1802. In some embodiments, the source/drain regions 312 may comprise highly doped regions (e.g., regions with a doping concentration of greater than 1×10¹⁸ cm⁻³, greater than 1×10¹⁹ cm⁻³, or other similar values) within the substrate 102. In such embodiments, the source/drain regions 312 may be formed by selectively implanting a dopant species into the substrate 102 according to a mask. The dopant species may comprise an n-type dopant (e.g., phosphorus, arsenic, antimony, bismuth, or the like) or a p-type dopant (e.g., boron, aluminum, gallium, indium, or the like). In other embodiments (not shown), the source/drain regions 312 may comprise highly doped epitaxial regions. In such embodiments, the source/drain regions 312 may be formed by selectively etching the substrate 102 to form source/drain recesses on opposing sides of the high-voltage sacrificial gate structure 1802 and subsequently forming a doped epitaxial material within the source/drain recesses.

In some embodiments (not shown), additional source/drain regions may be formed within the logic region 306 on opposing sides of the logic sacrificial gate structure 1804. In some embodiments, the additional source/drain regions may comprise highly doped epitaxial regions. In such embodiments, the additional source/drain regions may be formed by selectively etching a part of the one or more fins of semiconductor material 320 to form source/drain recesses on opposing sides of the logic sacrificial gate structure 1804 and subsequently forming a doped epitaxial material within the source/drain recesses.

After forming the source/drain regions 312, a first ILD layer 118a is formed over the substrate 102 and between sides of the second capacitor conductor 110, the high-voltage sacrificial gate structure 1802, and the logic sacrificial gate structure 1804. In some embodiments, the first ILD layer 118a may be formed by a deposition process (e.g., PVD, CVD, PE-CVD, ALD, or the like). In various embodiments, the first ILD layer 118a may comprise or be one or more of silicon dioxide, carbon doped silicon dioxide, silicon oxynitride, BSG, PSG, BPSG, FSG, USG, a porous dielectric material, or the like.

In some embodiments, a planarization process may be performed after forming the first ILD layer 118a over the substrate 102. The planarization process removes a part of the first ILD layer 118a to expose uppermost surfaces of the second capacitor conductor 110, the high-voltage sacrificial gate structure 1802, and the logic sacrificial gate structure 1804. In some embodiments, the planarization process may comprise a chemical mechanical polishing (CMP) process. In some embodiments, the planarization process may cause dishing along an uppermost surface of the second capacitor conductor 110. The dishing forms a recess 202 within the uppermost surface of the second capacitor conductor 110. The recess 202 is depressed below a topmost surface of the second capacitor conductor 110.

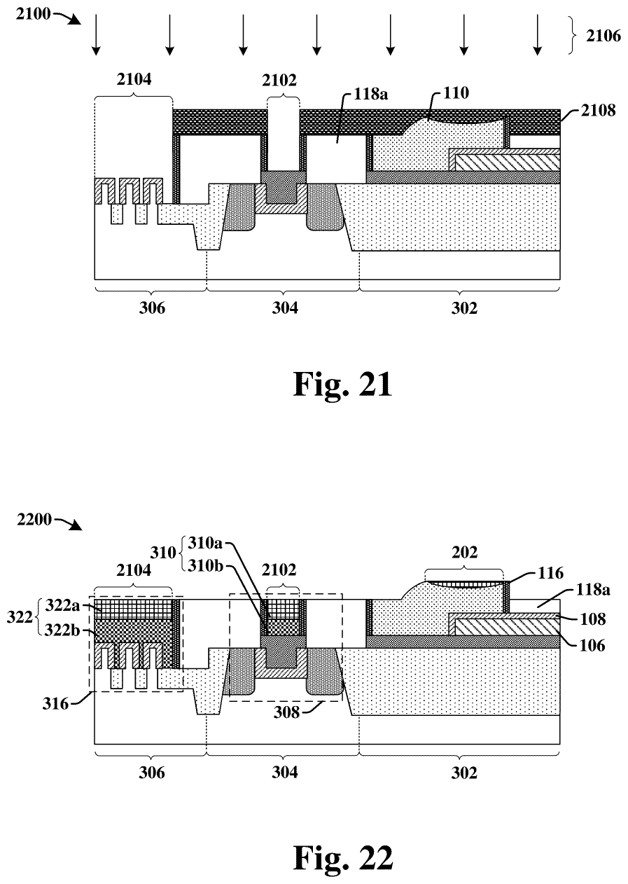

As shown in cross-sectional view 2100 of FIG. 21, the high-voltage sacrificial gate structure (1802 of FIG. 20) and the logic sacrificial gate structure (1804 of FIG. 20) are removed to form a high-voltage gate cavity 2102 and a logic gate cavity 2104. In some embodiments, the high-voltage sacrificial gate structure and the logic sacrificial gate structure may be removed by selectively exposing the high-voltage sacrificial gate structure and the logic sacrificial gate structure to an etchant 2106. In some embodiments, prior to removing the high-voltage sacrificial gate structure and the logic sacrificial gate structure, a mask 2108 may be formed over the capacitor region 302 to prevent the etchant 2106 from damaging the second capacitor conductor 110.

As shown in cross-sectional view 2200 of FIG. 22, a high-voltage gate structure 310 is formed within the high-voltage gate cavity 2102 and a logic gate structure 322 is formed within the logic gate cavity 2104. The high-voltage gate structure 310 forms a high-voltage transistor device 308 within the high-voltage region 304 and the logic gate structure 322 forms a logic transistor device 316 within the logic region 306. In some embodiments, the high-voltage gate structure 310 may comprise a high-voltage metal gate 310b and a high-voltage metal cap 310a disposed over the high-voltage metal gate 310b. In some embodiments, the logic gate structure 322 may comprise a logic metal gate 322b and a logic metal cap 322a disposed over the logic metal gate 322b. In various embodiments, the high-voltage gate structure 310 and the logic gate structure 322 may be formed by forming a metal gate layer followed by forming a metal cap layer. The metal gate layer and the metal cap layer may be formed using deposition techniques (e.g., CVD, PE-CVD, PVD, etc.) and/or a plating technique (e.g., an electroplating technique). A planarization process is subsequently performed after deposition of the metal cap layer to form the high-voltage gate structure 310 and the logic gate structure 322. In various embodiments, the metal layer may comprise or be an n-type metal (e.g., aluminum, tantalum, titanium, hafnium, or the like) or a p-type metal (e.g., nickel, cobalt, molybdenum, platinum, lead, gold, or the like). In various embodiments, the metal cap layer may comprise or be tungsten, ruthenium, titanium, and/or the like.

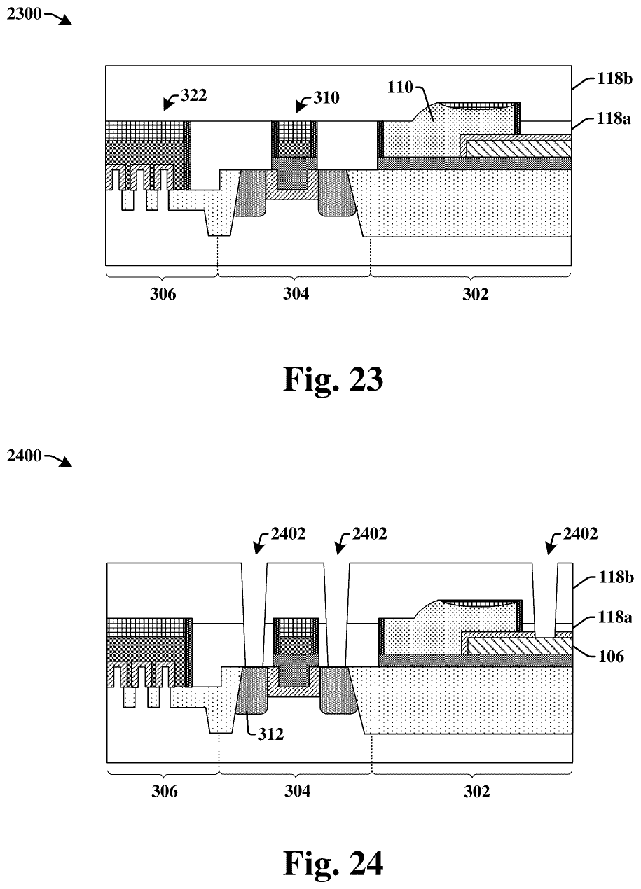

As shown in cross-sectional view 2300 of FIG. 23, a second ILD layer 118b is formed over the first ILD layer 118a, the second capacitor conductor 110, the high-voltage gate structure 310, and the logic gate structure 322. In some embodiments, the second ILD layer 118b may be formed by a deposition process (e.g., PVD, CVD, PE-CVD, ALD, or the like). In various embodiments, the second ILD layer 118b may comprise or be one or more of silicon dioxide, carbon doped silicon dioxide, silicon oxynitride, BSG, PSG, BPSG, FSG, USG, a porous dielectric material, or the like.

As shown in cross-sectional view 2400 of FIG. 24, a first plurality of contact openings 2402 are formed within the first ILD layer 118a and the second ILD layer 118b. The first plurality of contact openings 2402 vertically extend through the first ILD layer 118a and the second ILD layer 118b to expose the first capacitor conductor 106 within the capacitor region 302 and to further expose the source/drain regions 312 within the high-voltage region 304. In some embodiments, the first plurality of contact openings 2402 may be formed by selectively etching the first ILD layer 118a and the second ILD layer 118b according to a patterning process that exposes the first ILD layer 118a and the second ILD layer 118b to an etchant in areas not covered by a mask.

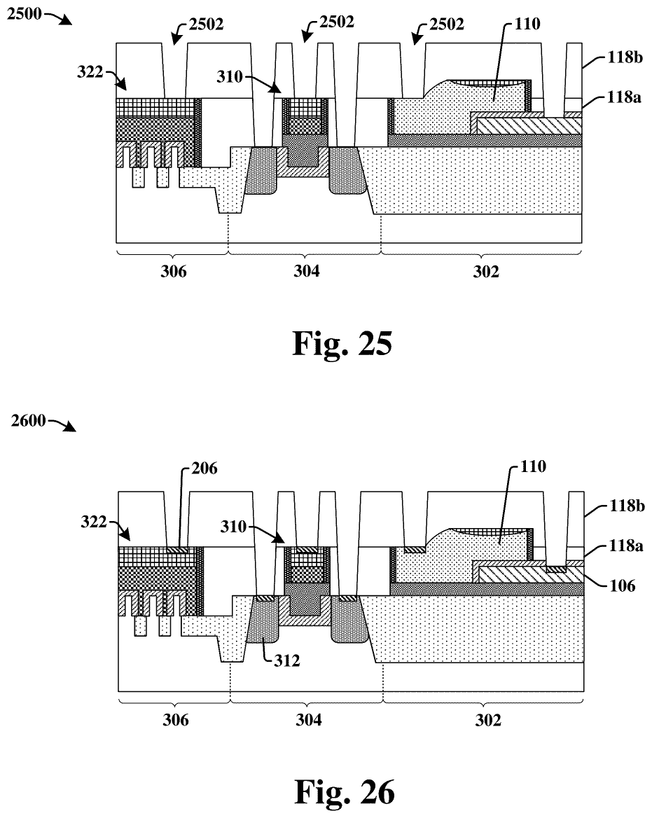

As shown in cross-sectional view 2500 of FIG. 25, a second plurality of contact openings 2502 are formed within the second ILD layer 118b. The second plurality of contact openings 2502 vertically extend through the second ILD layer 118b to expose the second capacitor conductor 110 within the capacitor region 302, the high-voltage gate structure 310 within the high-voltage region 304, and the logic gate structure 322 within the logic region 306. In some embodiments, the second plurality of contact openings 2502 may be formed by selectively etching the second ILD layer 118b according to a patterning process that exposes the second ILD layer 118b to an etchant in areas not covered by a mask.

As shown in cross-sectional view 2600 of FIG. 26, a salicidation process may be performed to form a silicide 206 on exposed surfaces of the first capacitor conductor 106, the second capacitor conductor 110, the source/drain regions 312, the high-voltage gate structure 310, and the logic gate structure 322. The salicidation process may be performed by depositing a metal, heating the integrated chip structure to integrate the metal into the exposed regions of the first capacitor conductor 106, the second capacitor conductor 110, the source/drain regions 312, the high-voltage gate structure 310, and the logic gate structure 322. Excess of the metal may be subsequently removed by etching.

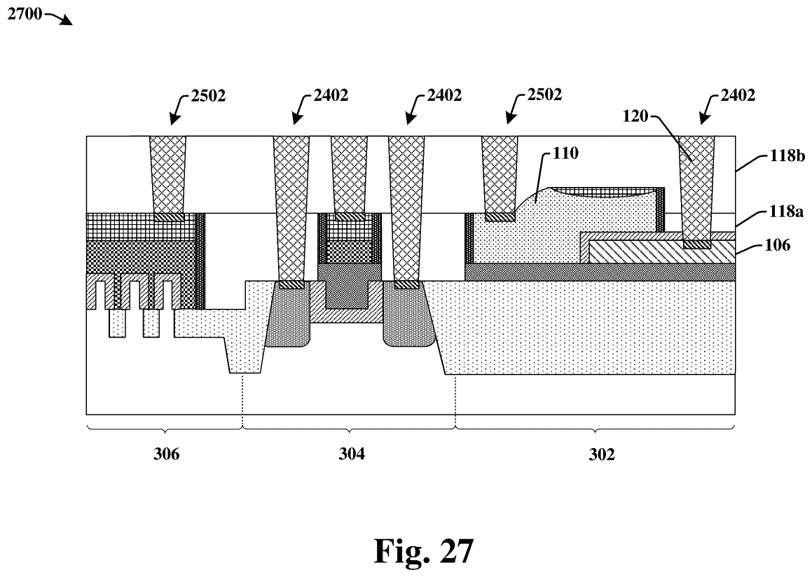

As shown in cross-sectional view 2700 of FIG. 27, a plurality of conductive interconnects 120 (e.g., conductive contacts) are formed within the first plurality of contact openings 2402 and the second plurality of contact openings 2502. In some embodiments, the conductive interconnects 120 may be formed by filling the first plurality of contact openings 2402 and the second plurality of contact openings 2502 with one or more conductive materials. In some embodiments, the one or more conductive materials may comprise tungsten, ruthenium, titanium, copper, aluminum, and/or the like. The one or more conductive materials may be formed by way of a deposition process (e.g., by CVD, PVD, ALD, sputtering, or the like) and/or a plating process (e.g., electrochemical plating, electroless plating, etc.). A planarization process (e.g., CMP) may be subsequently performed to remove excess of the one or more conductive materials from over the second ILD layer 118b and to form the plurality of conductive interconnects 120.

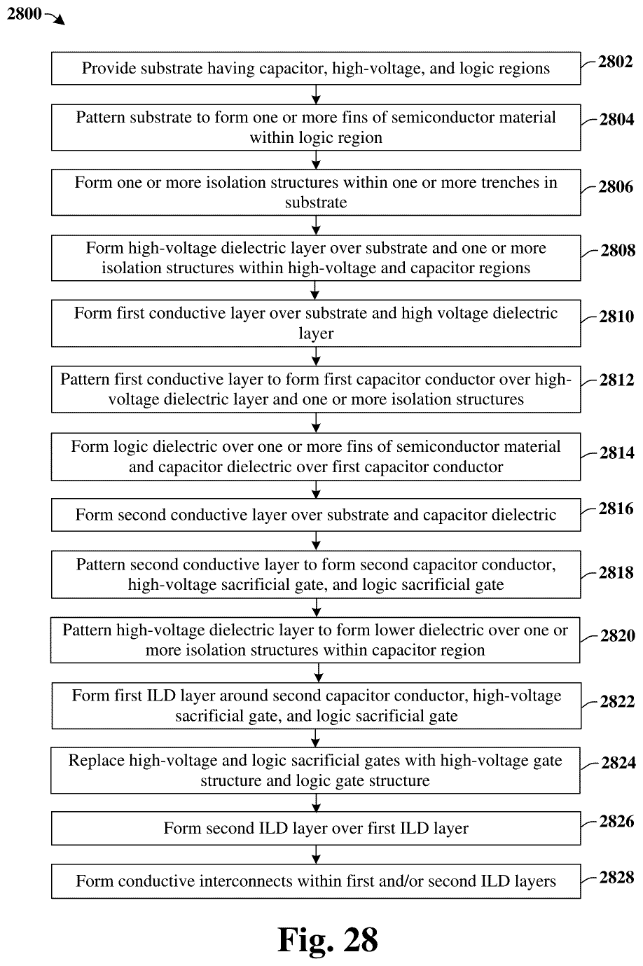

FIG. 28 illustrates a flow diagram of some embodiments of a method 2800 of forming an integrated chip comprising a disclosed FEOL capacitor integrated with FEOL transistor devices.

While method 2800 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases

At act 2802, a substrate having capacitor region, a high-voltage region, and a logic region is provided. FIG. 6 illustrates a cross-sectional view 600 of some embodiments corresponding to act 2802.

At act 2804, the substrate is patterned to form one or more fins of semiconductor material within the logic region. FIG. 7 illustrates a cross-sectional view 700 of some embodiments corresponding to act 2804.

At act 2806, one or more isolation structures are formed within one or more trenches in the substrate. FIGS. 8-9 illustrate cross-sectional views, 800 and 900, of some embodiments corresponding to act 2806.

At act 2808, a high-voltage dielectric layer is formed over the substrate and the one or more isolation structures within the high-voltage region and the capacitor region. FIG. 11 illustrates a cross-sectional view 1100 of some embodiments corresponding to act 2808.

At act 2810, a first conductive layer is formed over the substrate and the high-voltage dielectric layer. FIG. 12 illustrates a cross-sectional view 1200 of some embodiments corresponding to act 2810.

At act 2812, the first conductive layer is patterned to form first capacitor conductor over the high-voltage dielectric layer and the one or more isolation structures. FIG. 13 illustrates a cross-sectional view 1300 of some embodiments corresponding to act 2812.

At act 2814, a logic dielectric is formed over the one or more fins of semiconductor material and a capacitor dielectric is formed over the first capacitor conductor. FIG. 15 illustrates a cross-sectional view 1500 of some embodiments corresponding to act 2814.

At act 2816, a second conductive layer is formed over the substrate and the capacitor dielectric. FIG. 17 illustrates a cross-sectional view 1700 of some embodiments corresponding to act 2816.

At act 2818, the second conductive layer is patterned to form a second capacitor conductor, a high-voltage sacrificial gate structure, and a logic sacrificial gate structure. FIG. 18 illustrates a cross-sectional view 1800 of some embodiments corresponding to act 2818.

At act 2820, the high-voltage dielectric layer is patterned to form a lower dielectric over the one or more isolation structures within the capacitor region. FIG. 20 illustrates a cross-sectional view 2100 of some embodiments corresponding to act 2820.

At act 2822, a first inter-level dielectric (ILD) layer is formed around the second capacitor conductor, the high-voltage sacrificial gate structure, and the logic sacrificial gate structure. FIG. 20 illustrates a cross-sectional view 2100 of some embodiments corresponding to act 2822.

At act 2824, the high-voltage sacrificial gate structure and the logic sacrificial gate structure are replaced with a high-voltage gate structure and a logic gate structure. FIGS. 21-22 illustrate cross-sectional views, 2100 and 2200, of some embodiments corresponding to act 2824.

At act 2826, a second inter-level dielectric (ILD) layer is formed on the first ILD layer. FIG. 23 illustrates a cross-sectional view 2300 of some embodiments corresponding to act 2826.

At act 2828, conductive interconnects are formed within the first ILD layer and/or the second ILD layer. FIGS. 24-27 illustrate cross-sectional views 2400, 2500, 2600, and 2700 of some embodiments corresponding to act 2828.

Accordingly, the present disclosure relates to an integrated chip structure comprising a FEOL capacitor (e.g., a PIP capacitor) that is formed by a simple and low-cost fabrication process that uses process steps used to form other FEOL devices (e.g., high-voltage and logic transistor devices).

In some embodiments, the present disclosure relates to an integrated chip structure. The integrated chip structure includes a first capacitor conductor disposed over an isolation structure arranged within a substrate, the isolation structure laterally extending past opposing outer sidewalls of the first capacitor conductor; a capacitor dielectric arranged along one of the opposing outer sidewalls of the first capacitor conductor and over a top surface of the first capacitor conductor; and a second capacitor conductor arranged along an outer sidewall of the capacitor dielectric and over a top surface of the capacitor dielectric, the second capacitor conductor laterally overlapping parts of both the capacitor dielectric and the first capacitor conductor.

In other embodiments, the present disclosure relates to an integrated chip structure. The integrated chip structure includes a first capacitor conductor disposed over a substrate; a capacitor dielectric arranged on the first capacitor conductor; a second capacitor conductor separated from the first capacitor conductor by the capacitor dielectric, a recess being arranged along a top of the second capacitor conductor and laterally extending from directly over the first capacitor conductor to laterally outside of the first capacitor conductor; a metallic inset disposed within the recess in the second capacitor conductor; and an inter-level dielectric (ILD) structure extending from over the metallic inset to along opposing sides of the second capacitor conductor.

In yet other embodiments, the present disclosure relates to a method of forming an integrated chip structure. The method includes forming an isolation structure within a trench formed by sidewalls of a substrate; forming a high-voltage dielectric layer over the isolation structure and the substrate; forming a first conductive layer over the high-voltage dielectric layer; patterning the first conductive layer to form a first capacitor conductor over the high-voltage dielectric layer; forming a capacitor dielectric along sidewalls and an upper surface of the first capacitor conductor; forming a second conductive layer along a sidewall and an upper surface of the capacitor dielectric; patterning the second conductive layer to form a second capacitor conductor along the sidewall and the upper surface of the capacitor dielectric; and patterning the high-voltage dielectric layer to form a lower dielectric between the isolation structure and lower surfaces of the first capacitor conductor and the second capacitor conductor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip structure, comprising:
a first capacitor conductor disposed over an isolation structure arranged within a substrate, the isolation structure laterally extending past opposing outer sidewalls of the first capacitor conductor;
a capacitor dielectric arranged along one of the opposing outer sidewalls of the first capacitor conductor and over a top surface of the first capacitor conductor; and
a second capacitor conductor arranged along an outer sidewall of the capacitor dielectric and over a top surface of the capacitor dielectric, wherein the second capacitor conductor laterally overlaps parts of both the capacitor dielectric and the first capacitor conductor.

2. The integrated chip structure of claim 1, further comprising:
a transistor device arranged on the substrate; and
a first inter-level dielectric (ILD) layer having an uppermost surface at or below an uppermost surface of the second capacitor conductor, wherein the first ILD layer laterally separates the transistor device and the second capacitor conductor.

3. The integrated chip structure of claim 1, wherein the second capacitor conductor has a curved upper surface forming a recess that laterally extends from directly over the first capacitor conductor to laterally outside of the first capacitor conductor.

4. The integrated chip structure of claim 3, wherein the curved upper surface is recessed below a highest point of the second capacitor conductor that is laterally outside of the first capacitor conductor.

5. The integrated chip structure of claim 3, further comprising:
a metallic inset disposed within the recess in the second capacitor conductor; and
an inter-level dielectric (ILD) structure extending from over the metallic inset to along sidewalls of the second capacitor conductor.

6. The integrated chip structure of claim 5, further comprising:
a first conductive interconnect extending through the ILD structure to contact the first capacitor conductor; and
a second conductive interconnect vertically extending through the ILD structure to contact the second capacitor conductor, wherein the first conductive interconnect and the second conductive interconnect extend above a top of the metallic inset.

7. The integrated chip structure of claim 1, further comprising:
a lower dielectric disposed on an upper surface of the isolation structure and extending along bottommost surfaces of the first capacitor conductor and the second capacitor conductor.

8. An integrated chip structure, comprising:
a first capacitor conductor disposed over a substrate;
a capacitor dielectric arranged on the first capacitor conductor;
a second capacitor conductor separated from the first capacitor conductor by the capacitor dielectric, wherein a recess is arranged along a top of the second capacitor conductor and laterally extends from directly over the first capacitor conductor to laterally outside of the first capacitor conductor;
a metallic inset disposed within the recess in the second capacitor conductor; and
an inter-level dielectric (ILD) structure extending from over the metallic inset to along opposing sides of the second capacitor conductor.

9. The integrated chip structure of claim 8, further comprising:
a first sidewall spacer arranged along an outermost sidewall of the capacitor dielectric, wherein the capacitor dielectric laterally separates the first sidewall spacer from the first capacitor conductor;
a second sidewall spacer arranged along an upper surface of the capacitor dielectric and along a first outermost sidewall of the second capacitor conductor; and
a third sidewall spacer arranged along a second outermost sidewall of the second capacitor conductor.

10. The integrated chip structure of claim 9, wherein the first sidewall spacer, the second sidewall spacer, and the third sidewall spacer have topmost surfaces that are at different heights over the substrate.

11. The integrated chip structure of claim 10, further comprising:
an isolation structure disposed between sidewalls of the substrate;
a lower dielectric disposed on an upper surface of the isolation structure and laterally extending along bottommost surfaces of the first capacitor conductor and the second capacitor conductor; and
wherein the lower dielectric laterally extends from an outermost sidewall of the third sidewall spacer to laterally past an outermost sidewall of the first sidewall spacer.

12. The integrated chip structure of claim 11, further comprising:
a high-voltage transistor device comprising a high-voltage gate structure separated from the substrate by a first high-voltage gate dielectric and a second high-voltage gate dielectric over the first high-voltage gate dielectric, wherein the first high-voltage gate dielectric extends along sidewalls and a lower surface of the second high-voltage gate dielectric.

13. The integrated chip structure of claim 12, wherein the second high-voltage gate dielectric has an upper surface that is substantially co-planar with an upper surface of the lower dielectric.

14. The integrated chip structure of claim 12, wherein thicknesses of outermost sidewalls of the lower dielectric and the second high-voltage gate dielectric are substantially equal.

15. The integrated chip structure of claim 8, further comprising:
a logic transistor device comprising a logic gate structure separated from the substrate by a logic gate dielectric, wherein thicknesses of the capacitor dielectric and the logic gate dielectric are substantially equal.

16. A method of forming an integrated chip structure, comprising:
forming an isolation structure within a trench formed by sidewalls of a substrate;
forming a high-voltage dielectric layer over the isolation structure and the substrate;
forming a first conductive layer over the high-voltage dielectric layer;
patterning the first conductive layer to form a first capacitor conductor over the high-voltage dielectric layer;
forming a capacitor dielectric along sidewalls and an upper surface of the first capacitor conductor;
forming a second conductive layer along a sidewall and an upper surface of the capacitor dielectric;
patterning the second conductive layer to form a second capacitor conductor along the sidewall and the upper surface of the capacitor dielectric; and
patterning the high-voltage dielectric layer to form a lower dielectric between the isolation structure and lower surfaces of the first capacitor conductor and the second capacitor conductor.

17. The method of claim 16, further comprising:
selectively patterning the substrate to form a high-voltage gate dielectric recess within the substrate;
forming a first high-voltage gate dielectric within the high-voltage gate dielectric recess; and
patterning the high-voltage dielectric layer to form a second high-voltage gate dielectric over the first high-voltage gate dielectric and within the high-voltage gate dielectric recess.

18. The method of claim 17, further comprising:
patterning the substrate to form one or more fins of semiconductor material; and
forming a logic gate dielectric along sidewalls and an upper surface of the one or more fins of semiconductor material, wherein the logic gate dielectric is formed concurrent to forming the capacitor dielectric on the first capacitor conductor.

19. The method of claim 18, further comprising:
patterning the second conductive layer to form a high-voltage sacrificial gate structure over the second high-voltage gate dielectric and to further form a logic sacrificial gate structure over the logic gate dielectric.

20. The method of claim 19, further comprising:
removing the high-voltage sacrificial gate structure to form a high-voltage gate cavity;
removing the logic sacrificial gate structure to form a logic gate cavity;
forming a high-voltage gate structure within the high-voltage gate cavity; and
forming a logic gate structure within the logic gate cavity.
